(19) United States
(12) Patent Application Publication
(10) Pub. No.: US 2023/0232646 A1
(43) Pub. Date: Jul. 20, 2023

(54) LIGHT-EMITTING ELEMENT AND METHOD OF MANUFACTURING LIGHT-EMITTING ELEMENT

(71) Applicant: SHARP KABUSHIKI KAISHA, Sakai City, Osaka (JP)

(72) Inventors: Yukio TAKENAKA, Sakai City, Osaka (JP); MAKOTO IZUMI, Sakai City, Osaka (JP)

(21) Appl. No.: 17/927,776

(22) PCT Filed: May 26, 2020
(86) PCT No.: PCT/JP2020/020776

§ 371 Date: Nov. 25, 2022

(51) Int. Cl. H10K 50/115; H10K 71/00

(52) U.S. Cl. CPC H10K 50/115; H10K 71/00; H10K 2102/103

(57) ABSTRACT

A light-emitting layer (3) in a light-emitting element includes: a quantum dot (31); a plurality of first ligands (32) each including a first functional group (34) and a positively charged portion (35); a plurality of second ligands (33) each including a second functional group (41) and a negatively charged portion (42); and an ionic liquid (34) in which the quantum dot (31) is dispersed.

### TECHNICAL FIELD

The present invention relates to light-emitting elements including a light-emitting layer in which quantum dots are dispersed in a liquid and also to methods of manufacturing such light-emitting elements.

### BACKGROUND ART

Organic EL (electroluminescence) elements (OLEDs (organic light-emitting diodes)) including a liquid light-emitting layer have been proposed. By virtue of the inclusion of the liquid light-emitting layer, these OLEDs do not easily suffer from detachment between the light-emitting layer and a carrier injection layer when the organic EL elements are bent. The OLEDs are hence expected to be suited to flexible display devices.

The liquid (medium) in this light-emitting layer is often a molten salt, or an ionic liquid, that is molten at normal temperature. This molten salt does not evaporate because of its extremely low vapor pressure and is electrically conductive by ionic conduction.

Organic electroluminescence elements are known that include a light-emitting layer containing this molten salt and a light-emitting material (Patent Literature 1).

### CITATION LIST

### Patent Literature

Patent Literature 1: Japanese Patent Specification No. 5441308 (Registered Dec. 27, 2013)

### SUMMARY OF INVENTION

### Technical Problem

However, when the ionic liquid above is applied to QLEDs (quantum-dot light-emitting diodes), the quantum dots disadvantageously tend to aggregate in the ionic liquid because the quantum dots are larger in size than organic molecules in the ionic liquid.

### Solution to Problem

A display device in accordance with the present invention is a light-emitting element including: an anode; a cathode; and a light-emitting layer between the anode and the cathode, wherein the light-emitting layer includes: a quantum dot; a plurality of first ligands each including a first functional group coordinated to the quantum dot and further including a positively charged portion; a plurality of second ligands each including a second functional group coordinated to the quantum dot to which the plurality of first ligands are coordinated and further including a negatively charged portion; and a normal-temperature molten salt in which the quantum dot is dispersed.

A method of manufacturing a display device in accordance with the present invention is a method of manufacturing a light-emitting element, the method including: a step of forming an anode; a step of forming a cathode; and a step of forming a light-emitting layer, wherein the step of forming a light-emitting layer includes: a first step of forming a resin member in a frame shape on either the anode or the cathode; and a second step of forming: a quantum dot; a plurality of first ligands each including a first functional group coordinated to the quantum dot and further including a positively charged portion; a plurality of second ligands each including a second functional group coordinated to the quantum dot to which the plurality of first ligands are coordinated and further including a negatively charged portion; and a liquid normal-temperature molten salt in which the quantum dot is dispersed inside the frame-shaped resin member

Another method of manufacturing a display device in accordance with the present invention is a method of manufacturing a light-emitting element, the method including: a step of forming an anode; a step of forming a cathode; a step of attaching the anode and the cathode together; and a step of forming a light-emitting layer, wherein the step of attaching the anode and the cathode together includes: a first step of forming a resin member in a frame shape, except for a portion for a liquid-injection hole, on either the anode or the cathode; and a second step of attaching the anode and the cathode together and via the resin member, the step of forming a light-emitting layer includes: a step of injecting, between the anode and the cathode that are attached together via the liquid-injection hole, a liquid including: a quantum dot; a plurality of first ligands each including a first functional group coordinated to the quantum dot and further including a positively charged portion; a plurality of second ligands each including a second functional group coordinated to the quantum dot to which the plurality of first ligands are coordinated and further including a negatively charged portion; and a normal-temperature molten salt in which the quantum dot is dispersed; and subsequently to the step of injecting a liquid, a step of sealing the liquid-injection hole.

### Advantageous Effects of Invention

The present invention, in an aspect thereof, can provide a light-emitting element in which quantum dots are unlikely to aggregate in the ionic liquid and can also provide a method of manufacturing such a light-emitting element.

### BRIEF DESCRIPTION OF DRAWINGS

FIG. 1 is a cross-sectional view of a light-emitting element in accordance with Embodiment 1.

FIG. 2 is a cross-sectional view taken along line AA shown in FIG. 1.

FIG. 3 is a conceptual drawing illustrating a light-emitting layer in the light-emitting element.

FIG. 4 is a diagram showing a general formula of a candidate for a first ligand in the light-emitting layer.

FIG. 5 is a diagram showing another general formula of the candidate for the first ligand.

FIG. 6 is a diagram showing yet another general formula of the candidate for the first ligand.

FIG. 7 is a diagram showing still another general formula of the candidate for the first ligand.

FIG. 8 is a diagram representing a structure of the first ligand.

FIG. 9 is a diagram representing another structure of the first ligand.

FIG. 10 is a diagram showing a general formula of a candidate for a second ligand in the light-emitting layer.

FIG. 11 is a diagram showing another general formula of the candidate for the second ligand.

FIG. 12 is a diagram showing yet another general formula of the candidate for the second ligand.

FIG. 13 is a diagram representing a structure of the second ligand.

FIG. 14 is a diagram representing another structure of the second ligand.

FIG. 15 is a diagram illustrating ligand replacement.

FIG. 16 is a diagram illustrating ligand replacement.

FIG. 17 is a diagram illustrating ligand replacement.

FIG. 18 is a diagram illustrating ligand replacement.

FIG. 19 is a diagram illustrating graft modification.

FIG. 20 is a diagram illustrating graft modification.

FIG. 21 is a diagram illustrating graft modification.

FIG. 22 is a diagram illustrating graft modification.

FIG. 23 is a diagram illustrating graft modification.

FIG. 24 is a diagram illustrating graft modification.

FIG. 25 is a conceptual drawing illustrating a light-emitting layer in a light-emitting element in accordance with a comparative example.

FIG. 26 is a conceptual drawing illustrating a light-emitting layer in a light-emitting element in accordance with another comparative example.

FIG. 27 is a flow chart representing a method of manufacturing the light-emitting element in accordance with Embodiment 1.

FIG. 28 is a flow chart representing another method of manufacturing the light-emitting element.

FIG. 29 is a cross-sectional view of a light-emitting element in accordance with Embodiment 2.

FIG. 30 is a conceptual drawing illustrating a quantum dot in a light-emitting layer in a light-emitting element in accordance with Embodiment 3.

FIG. 31 is a conceptual drawing illustrating another quantum dot in the light-emitting layer.

FIG. 32 is a conceptual drawing illustrating of yet another quantum dot in the light-emitting layer.

FIG. 33 is a conceptual drawing illustrating of still another quantum dot in the light-emitting layer.

FIG. 34 is a conceptual drawing illustrating of yet still another quantum dot in the light-emitting layer.

FIG. 35 is a diagram illustrating a method of modifying the quantum dot by modification group replacement.

FIG. 36 is a diagram illustrating a method of modifying the quantum dot by graft modification.

FIG. 37 is a diagram illustrating another method of modifying the quantum dot by graft modification.

FIG. 38 is a diagram illustrating yet another method of modifying the quantum dot by graft modification.

FIG. 39 is a diagram illustrating still another method of modifying the quantum dot by graft modification.

FIG. 40 is a diagram illustrating yet still another method of modifying the quantum dot by graft modification.

FIG. 41 is a diagram illustrating an exemplary ionic liquid.

FIG. 42 is a diagram illustrating another exemplary ionic liquid.

FIG. 43 is a diagram illustrating yet another exemplary ionic liquid.

### DESCRIPTION OF EMBODIMENTS

### Embodiment 1

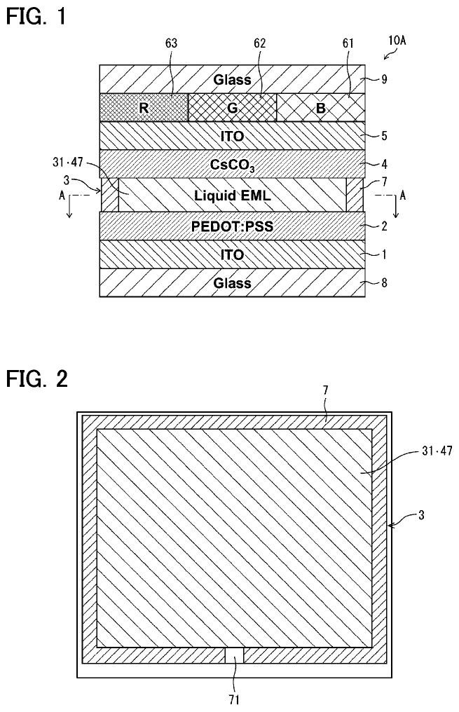

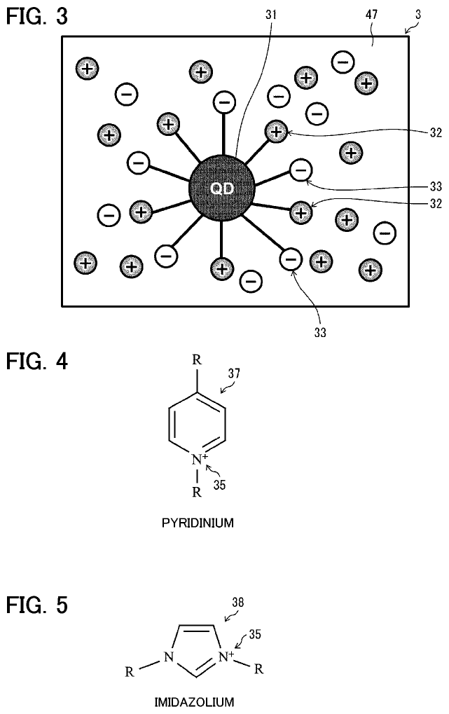

FIG. 1 is a cross-sectional view of a light-emitting element 10A in accordance with Embodiment 1. FIG. 2 is a cross-sectional view taken along line AA shown in FIG. 1. FIG. 3 is a conceptual drawing illustrating a light-emitting layer 3 in the light-emitting element 10A.

The light-emitting element 10 includes: an anode 1 containing ITO (indium tin oxide); a hole transportation layer (HTL) 2 containing PEDOT:PSS; the light-emitting layer 3; an electron transportation layer (ETL) 4 containing CsCO₃; and a cathode 5 containing ITO, all of which are provided in this order on a glass substrate 8.

The light-emitting layer 3 includes: an ionic liquid 47 (liquid normal-temperature molten salt); and a spacer 7 (frame-shaped resin member) provided between the hole transportation layer 2 and the electron transportation layer 4 to seal this ionic liquid 47. The ionic liquid 47, containing dispersed quantum dots 31, is sealed inside the space surrounded by the spacer 7.

The spacer 7 may be, for example, a resin material or another sealing material used in the art. The spacer 7 may be made of any material including an acrylic resin, an epoxy resin, a fluorine-based resin, a silicon-based resin, a rubber-based resin, and an ester-based resin. Preferred among these examples is an epoxy resin for its moisture resistance. Especially preferred epoxy resins include thermosetting epoxy resins and photocuring epoxy resins.

The spacer 7 is provided in advance with a liquid-injection hole 71 in a portion thereof, so as to allow injection of the ionic liquid 47 in which the quantum dots 31 are dispersed. The ionic liquid 47 can be injected by the same method as the liquid crystal. As described here, the spacer 7 may have the liquid-injection hole 71 which is sealed after the ionic liquid 47 containing the dispersed quantum dots 31 is injected. In addition, the ionic liquid 47 may be injected by applying the ionic liquid 47 onto the hole transportation layer 2 by, for example, inkjet printing and thereafter stacking the electron transportation layer 4 thereon, without providing the liquid-injection hole 71 in advance in a part of the spacer 7.

There are provided, on the cathode 5, a wavelength conversion layer 63 for converting the light emitted by the light-emitting layer 3 to red light, a wavelength conversion layer 62 for converting the light to green light, and a wavelength conversion layer 61 for converting the light to blue light. A glass substrate 9 is provided on the wavelength conversion layers 61, 62, 63.

The anode 1, the hole transportation layer 2, the electron transportation layer 4, and the cathode 5 may be made of a material selected from publicly known, conventional materials.

Voids in the hole transportation layer 2 and the electron transportation layer 4 are preferably small with a view to retaining the ionic liquid 47. Therefore, the hole transportation layer 2 preferably includes a thin film of the material for the hole transportation layer 2, and the electron transportation layer 4 preferably includes a thin film of the material for the electron transportation layer 4.

The light-emitting layer 3 contains: the plurality of quantum dots 31; a plurality of first ligands 32 coordinated to the quantum dots 31; a plurality of second ligands 33 coordinated to the quantum dots 31 to which the plurality of first ligands 32 are coordinated; and the ionic liquid 47 in which the quantum dots 31 are dispersed. The quantum dots 31 may also be made of any material including publicly known materials where suitable.

Some of the plurality of quantum dots 31 preferably emit light in the red wavelength region (640 nm to 770 nm; hereinafter may be referred to as “red light”), some of the plurality of quantum dots 31 preferably emit light in the green wavelength region (490 nm to 550 nm; hereinafter may be referred to as “green light”), and some of the plurality of quantum dots 31 preferably emit light in the blue wavelength region (430 nm to 490 nm; hereinafter may be referred to as “blue light”), such that the light-emitting layer 3 can emit white light.

The ionic liquid 47 contains a molten salt. This “molten salt” refers to a salt that exhibits liquid properties at normal temperature. The molten salt is typically made of inorganic or organic cations and inorganic or organic anions and has, for example, a high evaporation temperature, a high ionic conductance, heat resistance, and flame retardancy.

The molten salt may be, for example, the polymer compound of chemical formula 2 below.

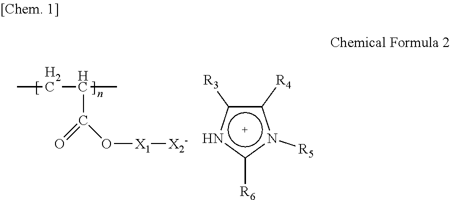

where X₁ is a substituted or unsubstituted C₁-C₁₀ alkylene group, a substituted or unsubstituted C₆-C₃₀ arylene group, a substituted or unsubstituted C₁-C₂₀ heteroalkylene group, or a substituted or unsubstituted C₄-C₃₀ heteroarylene group.

X₂⁻ is a sulfonate-based anion or a carboxylate-based anion.

R₃, R₄, R₅, and R₆ are each independently a hydrogen atom, a halogen atom, a carboxyl group, an amino group, a nitro group, a cyano group, a hydroxy group, a substituted or unsubstituted C₁-C₂₀ alkyl group, a substituted or unsubstituted C₁-C₂₀ alkoxy group, a substituted or unsubstituted C₁-C₂₀ silicon-containing group, a substituted or unsubstituted C₁-C₂₀ fluorine-containing group, a substituted or unsubstituted C₂-C₂₀ alkenyl group, a substituted or unsubstituted C₂-C₂₀ alkynyl group, a substituted or unsubstituted C₁-C₂₀ heteroalkyl group, a substituted or unsubstituted C₆-C₃₀ aryl group, a substituted or unsubstituted C₇-C₃₀ arylalkyl group, a substituted or unsubstituted C₅-C₃₀ heteroaryl group, or a substituted or unsubstituted C₃-C₃₀ heteroarylalkyl group.

“n” is an integer from 50 to 500.

The total content of the red light-emitting quantum dots, the green light-emitting quantum dots, and the blue light-emitting quantum dots to the ionic liquid 47 is preferably from 0.5 wt % to 10 wt %.

Theoretically, the ratio of the first ligands 32 and the second ligands 33 is preferably from 35:65 to 65:35.

The light-emitting layer 3, containing the ionic liquid 47, preferably has a thickness of from 50 nm to 1,000 nm, both inclusive.

The quantum dot 31 has, coordinated thereto, at least the positively charged, first ligands 32 and at least the negatively charged, second ligands 33.

The light-emitting layer 3 may further contain a porous resin (e.g., olefin-based resin) for retaining the ionic liquid 47 containing the normal-temperature molten salt.

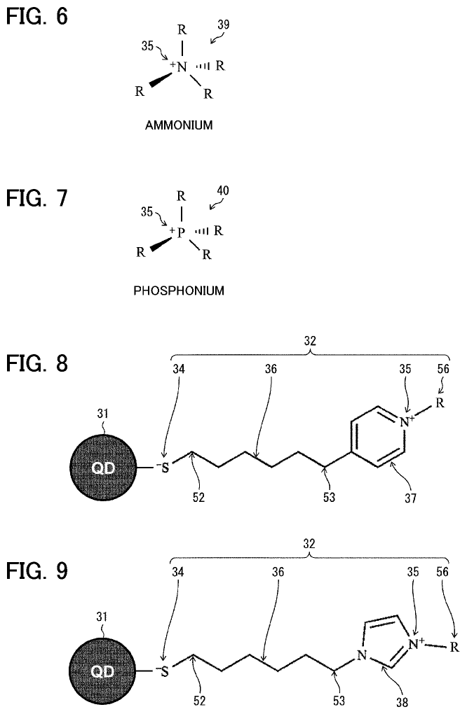

FIG. 4 is a diagram showing a general formula of a candidate for the first ligand 32 in the light-emitting layer 3. FIG. 5 is a diagram showing another general formula of the candidate. FIGS. 6 and 7 are diagrams showing yet other general formulae of the candidate.

FIG. 8 is a diagram representing a structure of the first ligand 32. FIG. 9 is a diagram representing another structure of the first ligand 32.

The first ligand 32 is specifically selected from the general formula of a pyridinium group 37 shown in FIG. 4, the general formula of an imidazolium group 38 shown in FIG. 5, the general formula of an ammonium group 39 shown in FIG. 6, and the general formula of a phosphonium group 40 shown in FIG. 7. Referring to FIGS. 4 to 7, the pyridinium group 37, the imidazolium group 38, the ammonium group 39, and the phosphonium group 40, all of which are candidates for the first ligand 32, include a cation-containing, positively charged portion 35.

As shown in FIGS. 8 and 9, the first ligand 32 includes: a first functional group 34 coordinated to the quantum dot 31; a positively charged, positively charged portion 35; a first main chain 36 of a saturated or unsaturated C₃-C₂₀ hydrocarbon between the first functional group 34 and the positively charged portion 35; and an alkyl group 56. The positively charged portion 35 can better restrain the aggregation of the quantum dots 31 when located farther away from the quantum dot 31. The positively charged portion 35 is therefore contained in the functional group (pyridinium group 37) that is bonded to a carbon 53 that is located farthest along the first main chain 36 from a carbon 52 to which the first functional group 34 is bonded.

In the general formulae shown in FIGS. 4 to 7, as shown in FIGS. 8 and 9, one of the plural R's includes, at an end thereof, the first functional group 34 coordinated to the quantum dot 31. Specifically, this R includes a C₂-C₂₀ alkyl chain and has, for example, a thiol group, a carboxyl group, or an amino group at an end thereof. Each R that has no functional group is a C₁-C₅ alkyl group 56 or a H atom.

The ionic liquid 47 contains counter anions for the cations of the first ligands 32 shown in FIGS. 4 to 7. These counter anions are selected from, for example, Li⁺, Na⁺, K⁺, Rb⁺, and Cs⁺.

When the first functional group 34 and the positively charged portion 35 of the first ligand 32 are separated by five or more carbon atoms along the first main chain 36 in this manner, the distances between the plurality of quantum dots 31 can be sufficiently maintained. That in turn further improves the dispersibility of the quantum dots 31 in the ionic liquid 47.

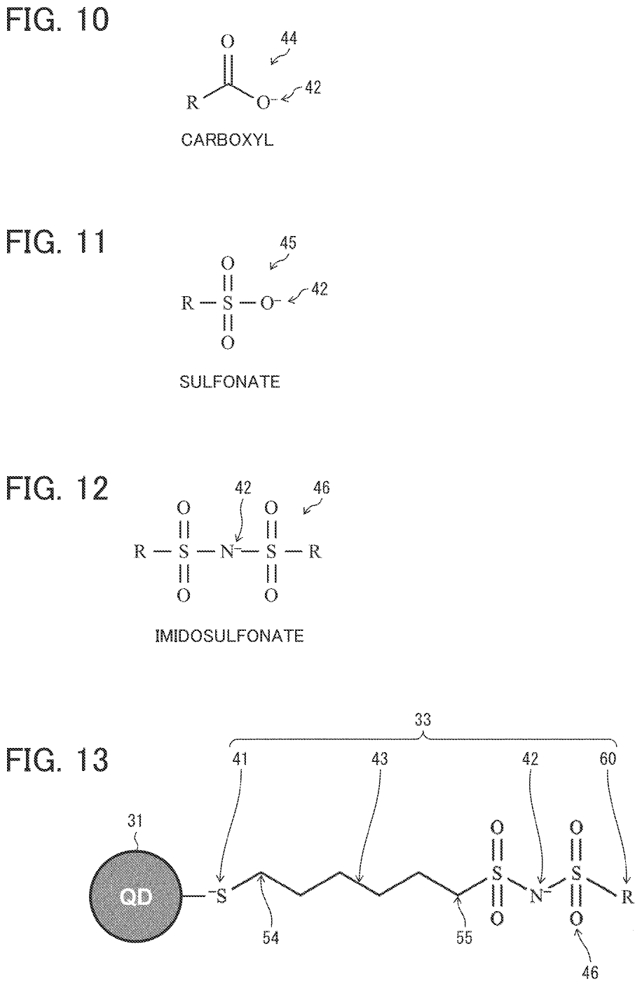

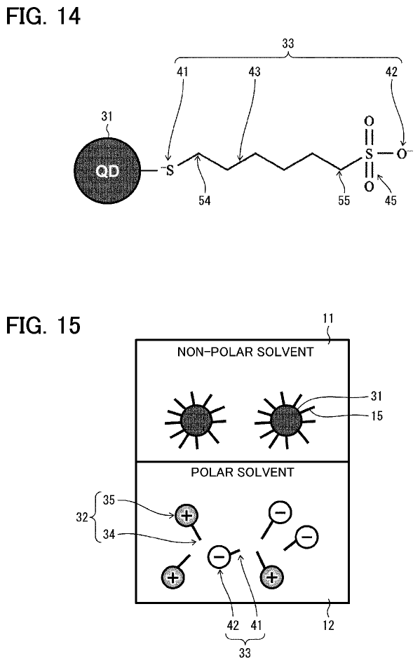

FIG. 10 is a diagram showing a general formula of a candidate for the second ligand 33 in the light-emitting layer 3. FIG. 11 is a diagram showing another general formula of the candidate. FIG. 12 is a diagram showing yet another general formula of the candidate. FIG. 13 is a diagram representing a structure of the second ligand 33. FIG. 14 is a diagram representing another structure of the second ligand 33.

The second ligand 33 is specifically selected from the general formula of a carboxyl group 44 shown in FIG. 10, the general formula of a sulfonium group 45 shown in FIG. 11, and the general formula of an imidesulfonium group 46 shown in FIG. 12. Referring to FIGS. to 12, the carboxyl group 44, the sulfonium group 45, and the imidesulfonium group 46, all of which are candidates for the second ligand 33, include an anion-containing, negatively charged portion 42.

In the general formulae shown in FIGS. 10 to 12, one of the R in the carboxyl group 44, the R in the sulfonium group 45, and the plurality of R's in the imidesulfonium group 46 includes, at an end thereof, a second functional group 41 coordinated to the quantum dot 31 as shown in FIGS. 13 and 14. Specifically, this R includes a C₂-C₂₀ alkyl chain and has, for example, a thiol group, a carboxyl group, or an amino group at an end thereof. Each R that has no second functional group 41 may be a C₁-C₅ alkyl group or a H atom.

The ionic liquid 47 contains counter cations for the anions shown in FIGS. 10 to 12. These counter cations are selected from, for example, BF⁴⁻, PF⁶⁻, Cl⁻, Br⁻, and I⁻.

As shown in FIG. 13, the second ligand 33 includes: a second functional group 41 coordinated to the quantum dot 31; a negatively charged, negatively charged portion 42; a second main chain 43 of a saturated or unsaturated C₃-C₂₀ hydrocarbon between the second functional group 41 and the negatively charged portion 42; and an alkyl group 60. The negatively charged portion 42 can better restrain the aggregation of the quantum dots 31 when located farther away from the quantum dot 31. The negatively charged portion 42 is therefore contained in the functional group (imidesulfonium group 46) that is bonded to a carbon 55 that is located farthest along the second main chain 43 from a carbon 54 to which the second functional group 41 is bonded.

As shown in FIG. 14, the second ligand 33 includes: a second functional group 41 coordinated to the quantum dot 31; a negatively charged, negatively charged portion 42; and a second main chain 43 of a saturated or unsaturated C₃-C₂₀ hydrocarbon between the second functional group 41 and the negatively charged portion 42. The negatively charged portion 42 is contained in the functional group (sulfonium group 45) that is bonded to a carbon 55 that is located farthest along the second main chain 43 from the carbon 54 to which the second functional group 41 is bonded.

When the second functional group 41 and the negatively charged portion 42 of the second ligand 33 are separated by three or more carbon atoms along the second main chain 43 in this manner, the distances between the plurality of quantum dots 31 can be sufficiently maintained. That in turn further improves the dispersibility of the quantum dots 31 in the ionic liquid 47.

As well as the plurality of quantum dots 31 to which the first ligands 32 and the second ligands 33 are coordinated, the plurality of quantum dots 31 to which no first ligands 32 or second ligands 33 are coordinated may be dispersed in the ionic liquid 47.

The quantum dot 31 including the plurality of first ligands 32 and the plurality of second ligands 33 can better restrain the aggregation of the quantum dots 31 when the number of the positively charged, positively charged portions 35 is closer to the number of the negatively charged, negatively charged portions 42. In the quantum dot 31 including the plurality of first ligands 32 and the plurality of second ligands 33, the number of the positively charged, positively charged portions 35 is therefore preferably from 0.8 times to 1.2 times, both inclusive, the number of the negatively charged, negatively charged portions 42.

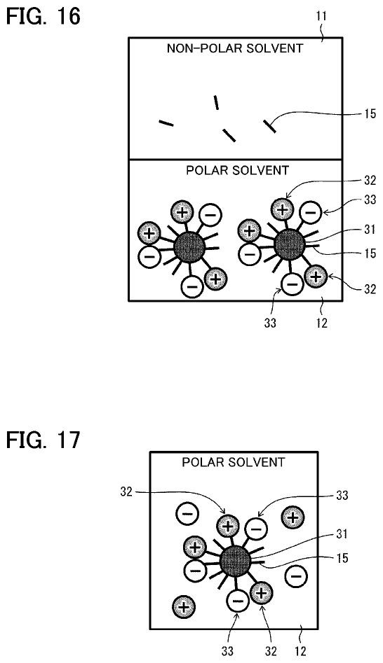

FIGS. 15 to 18 are diagrams illustrating ligand replacement. A non-polar solvent 11 such as toluene or octane and a polar solvent 12 such as water and acetonitrile separate out into different layers. Then, as shown in FIG. 15, the quantum dots 31 with ligands 15 are dispersed in the non-polar solvent 11. The first ligands 32 each including the first functional group 34 and the positively charged portion 35 and the second ligands 33 each including the second functional group 41 and the negatively charged portion 42 are dispersed in the polar solvent 12. Next, with the polar solvent 12 and the non-polar solvent 11 still being separated as two different layers, as the whole matter is reacted at 0° C. to 100° C. under stirring for 1 to 24 hours, the quantum dots 31 move from the non-polar solvent 11 to the polar solvent 12 while replacing the ligands 15 with the first ligands 32 and the second ligands 33 as shown in FIG. 16. In this state, the first ligands 32 and the second ligands 33 in the polar solvent 12 preferably have a higher concentration the ligands 15 in the non-polar solvent 11.

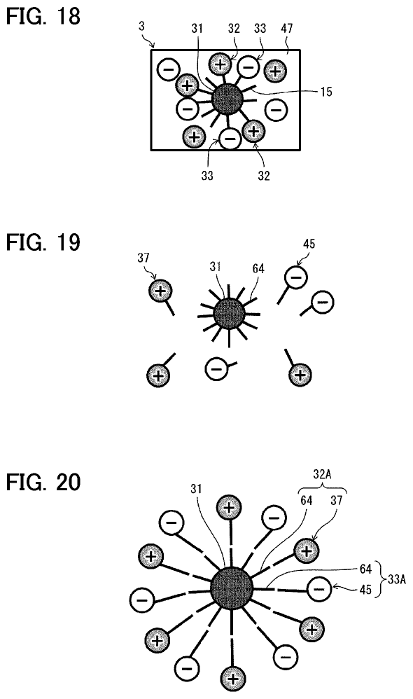

Next, when the polar solvent 12 is extracted, the ionic liquid 47 is mixed, and the polar solvent 12 is dried by, for example, heating as shown in FIG. 17, the quantum dots 31 having the first ligands 32, the second ligands 33, and the ligands 15 and dispersed in the ionic liquid 47 are obtained as shown in FIG. 18.

The quantum dots 31 with the first ligands 32, the second ligands 33, and the ligands may be applied to the light-emitting element 10A with the polar solvent 12 still being mixed with the ionic liquid 47 so that the polar solvent 12 can be subsequently dried and vaporized or may be applied to the light-emitting element 10A after the polar solvent 12 mixed with the ionic liquid 47 is dried and vaporized.

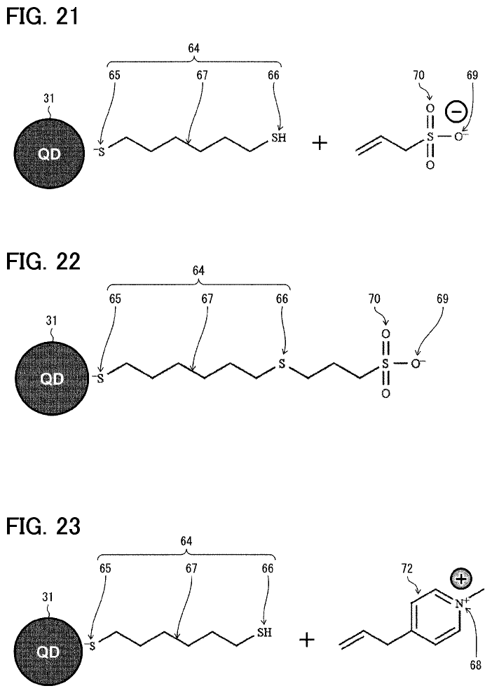

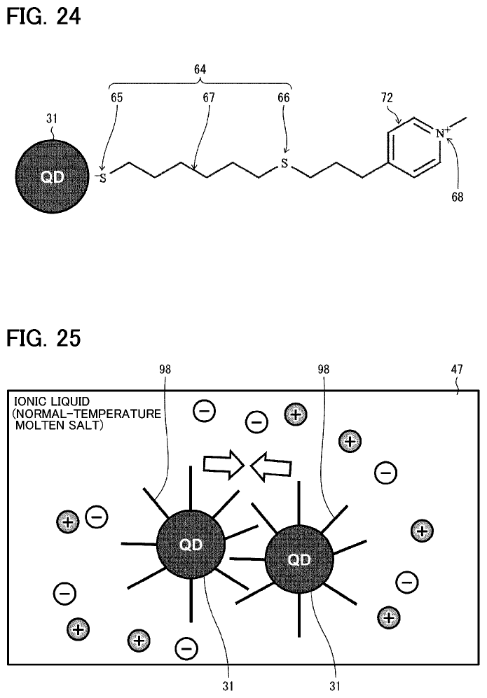

FIGS. 19 to 24 are diagrams illustrating graft modification. If the ligand has another reactive functional group other than the functional group located at the site where the ligand is bonded to the quantum dot 31, yet another ionic functional group can be appended to the other functional group without having to replace the ligand as described above in FIG. 16.

The quantum dot 31 has a graft modification ligand 64. The graft modification ligand 64 includes: a functional group 65 located at the site where the functional group 65 can be bonded to the quantum dot 31; a functional group 66 located at the site opposite the quantum dot 31; and a main chain 67 located between the functional groups 65, 66.

In this state, it is especially preferred that a thiol-ene reaction be used, because the reaction produces no by-products. First, quantum dots modified by a ligand having two thiol groups are mixed with: vinyl groups; molecules with a functional group including an ion; and a radical generator such as dihalogen or an azo compound. The mixture is then dispersed in a bipolar solvent such as ethyl acetate. Next, as radicals are generated under light or by heating, a functional group 72 with a positively charged portion 68 or a functional group 70 with a negatively charged portion 69 is appended to the functional group 66 at the end of the graft modification ligand 64 of the quantum dot 31.

Next, by mixing the solvent with an ionic liquid and drying the polar solvent by, for example, heating, quantum dots dispersed in the ionic liquid and having an ionic functional group are obtained.

These quantum dots may be applied to the light-emitting element 10A with the polar solvent still being mixed with the ionic liquid so that the polar solvent can be subsequently dried and vaporized or may be applied to the light-emitting element 10A after the polar solvent mixed with the ionic liquid is dried and vaporized.

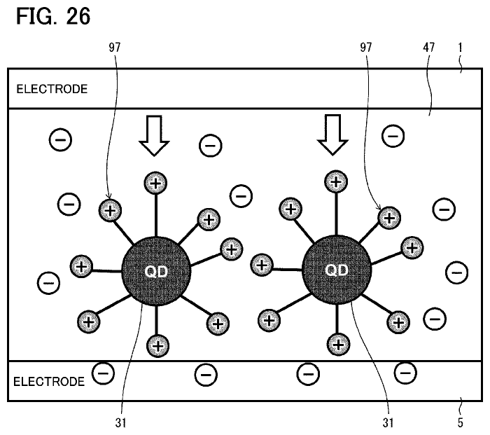

FIG. 25 is a conceptual drawing illustrating a light-emitting layer in a light-emitting element in accordance with a comparative example. FIG. 26 is a conceptual drawing illustrating a light-emitting layer in a light-emitting element in accordance with another comparative example.

The quantum dot 31 includes a ligand 98 that is typically a low-polarity, long chain alkyl group. Even when the quantum dots 31 with the low-polarity ligand 98 are dispersed in the ionic liquid 47 in this manner, the quantum dots 31 tend to aggregate as shown in FIG. 25 because the ionic liquid 47 in the solvent has a different polarity from the quantum dots 31. This aggregation of the quantum dots 31 disadvantageously lowers the luminous efficiency of the light-emitting layer.

When the ionic portions of ligands 97 of the quantum dots 31 are only charged with a single polarity, for example, when the ionic portions of the ligands 97 are only positively charged as shown in FIG. 26, the quantum dots 31, although exhibiting good dispersibility in the ionic liquid 47, are displaced toward the anode 1 or the cathode 5 in the ionic liquid 47 in the light-emitting layer of the light-emitting element that is an electroluminescence element due to electrophoresis. Therefore, the aggregation of the quantum dots 31 and the interaction between the anode 1, the cathode 5, and the quantum dots 31 are more likely to occur, which again disadvantageously lowers the luminous efficiency of the light-emitting layer.

In contrast, in the light-emitting element 10A in accordance with Embodiment 1, the quantum dots 31 to which the first ligands 32 with the positively charged, positively charged portion 35 and the second ligands 33 with the negatively charged, negatively charged portion 42 are coordinated are dispersed in the ionic liquid 47. Since the ionic liquid 47 is conductive, the quantum dots 31 to which the first ligands 32 with the positively charged, positively charged portion 35 and the second ligands 33 with the negatively charged, negatively charged portion 42 are coordinated exhibit increased dispersibility. The displacement of the quantum dots 31 toward the anode 1 or the cathode 5 due to electrophoresis is hence restrained. Consequently, the quantum dots 31 are unlikely to aggregate even after a period of time. The luminous efficiency of the light-emitting layer 3 is therefore unlikely to fall, which solves the problems of the comparative examples shown in FIGS. 25 and 26.

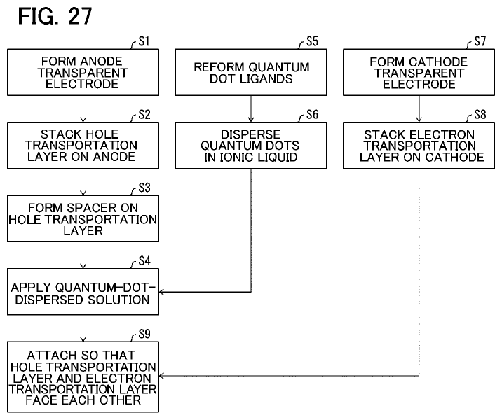

FIG. 27 is a flow chart representing a method of manufacturing the light-emitting element 10A in accordance with Embodiment 1. First, the anode 1, which is a transparent electrode, is formed on the substrate 8 (step S1). Then, the hole transportation layer 2 is stacked on the anode 1 (step S2). Next, the spacer 7 containing an ultraviolet-curing resin is formed on the hole transportation layer 2 by, for example, photolithography (step S3).

In addition, the ligands 15 of the quantum dots 31 are reformed in advance by, for example, graft modification of ionic functional groups (step S5). The quantum dots 31 with the reformed ligands 15 are then dispersed in the ionic liquid 47 (step S6).

Next, the quantum dots 31 with the reformed ligands 15 are applied onto the hole transportation layer 2 on which the spacer 7 is formed (step S4).

Additionally, the cathode 5, which is a transparent electrode, is formed in advance (step S7). The electron transportation layer 4 is then stacked on the cathode 5 (step S8).

Thereafter, the anode 1 and the cathode 5 are attached together in such a manner that the hole transportation layer 2 is located opposite the electron transportation layer 4 (step S9).

The hole transportation layer 2 and the electron transportation layer 4 can be formed by a publicly known, conventional method.

Note that the light-emitting layer 3 may be formed by stacking a porous resin (polyolefin) on the hole transportation layer 2 and permeating the hole transportation layer 2 with the ionic liquid 47.

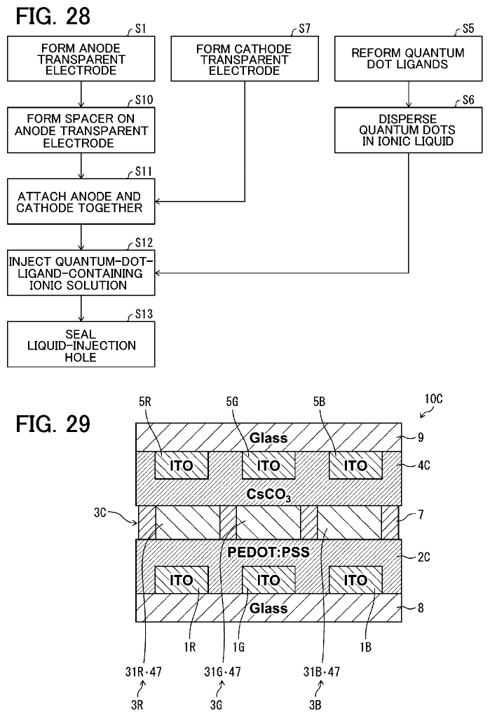

FIG. 28 is a flow chart representing another method of manufacturing the light-emitting element 10A. Members of the present embodiment that are similar to those described earlier are indicated by similar reference numerals, and detailed description thereof is not repeated.

First, the anode 1, which is a transparent electrode, is formed on the substrate 8 (step S1). Then, the spacer 7 with the liquid-injection hole 71 is formed on the anode 1 (transparent electrode) (step S10).

Additionally, the cathode 5, which is a transparent electrode, is formed in advance (step S7). The cathode 5 and the anode 1 on which the spacer 7 with the liquid-injection hole 71 is formed are then attached together (step S1).

In addition, the ligands 15 of the quantum dots 31 are reformed in advance by, for example, graft modification of ionic functional groups (step S5). The quantum dots 31 with the reformed ligands 15 are then dispersed in the ionic liquid 47 (step S6).

Next, the ionic liquid 47 in which the quantum dots 31 with the reformed ligands 15 are dispersed is injected through the liquid-injection hole 71 in the spacer 7 (step S12). Then, after spin-coating and baking at 100° C. for 1 hour, the solvent is completely removed in a vacuum oven, to form an 80-nm thick light-emitting layer. Thereafter, the liquid-injection hole 71 is sealed (step S13).

Note that the hole transportation layer 2 may be stacked on the anode 1 so that the spacer 7 with the liquid-injection hole 71 can be formed on the hole transportation layer 2.

### Embodiment 2

FIG. 29 is a cross-sectional view of a light-emitting element 10C in accordance with Embodiment 2. Members of the present embodiment that are similar to those described earlier are indicated by similar reference numerals, and detailed description thereof is not repeated.

The light-emitting element 10C includes quantum dots 31R, 31G, 31B in each red light-emitting, red light-emitting layer 3R, green light-emitting, green light-emitting layer 3G, and blue light-emitting, blue light-emitting layer 3B. Then, ionic liquids 47 containing the quantum dots 31R, 31G, 31B for red, green, and blue colors respectively are separated from each other by a spacer 7.

The light-emitting element 10C includes a glass substrate 8. An anode 1R corresponding to red light, an anode 1G corresponding to green light, and an anode 1B corresponding to blue light are formed on the substrate 8. A hole transportation layer 2C containing PEDOT:PSS is formed on the substrate 8 so as to cover the anodes 1R, 1G, 1B. The electron transportation layer 4C containing CsCO₃ is then formed on the red light-emitting layer 3R, the green light-emitting layer 3G, and the blue light-emitting layer 3B. A cathode 5R corresponding to the anode 1R, a cathode 5G corresponding to the anode 1G, and a cathode 5B corresponding to the anode 1B are formed so as to be embedded in the electron transportation layer 4C. A glass substrate 9 is disposed on the electron transportation layer 4C.

A light-emitting layer 3C includes: the ionic liquid 47 containing the quantum dots 31R; the ionic liquid 47 containing the quantum dots 31G; the ionic liquid 47 containing the quantum dots 31B; and the spacer 7 provided between the hole transportation layer 2C and the electron transportation layer 4C to separate these ionic liquids 47 from each other.

### Embodiment 3

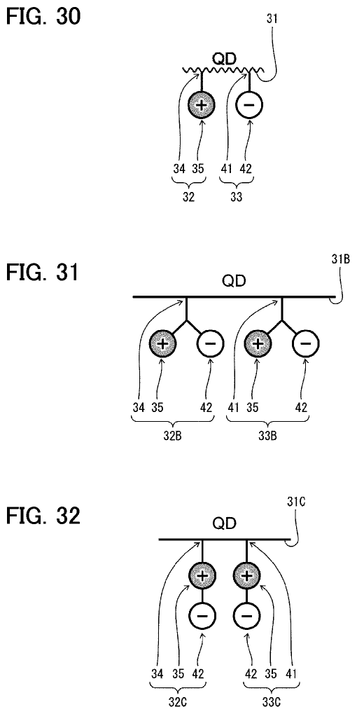

FIG. 30 is a conceptual drawing illustrating a quantum dot 31 in a light-emitting layer in a light-emitting element in accordance with Embodiment 3. Members of the present embodiment that are similar to those described earlier are indicated by similar reference numerals, and detailed description thereof is omitted.

A first ligand 32 and a second ligand 33 are coordinated to the quantum dot 31. The first ligand 32 includes a first functional group 34 and a positively charged portion 35. The second ligand 33 includes a second functional group 41 and a negatively charged portion 42. As described here, the first ligand 32 includes a first functional group 34 and a portion that is only positively charged, whereas the second ligand 33 includes a second functional group 41 and a portion that is only negatively charged.

FIG. 31 is a conceptual drawing illustrating another quantum dot 31B. Members of the present embodiment that are similar to those described earlier are indicated by similar reference numerals, and detailed description thereof is omitted.

A first ligand 32B and a second ligand 33B are coordinated to the quantum dot 31B. The first ligand 32B includes a first functional group 34, a positively charged portion 35, and a negatively charged portion 42. The positively charged portion 35 and the negatively charged portion 42 are positioned parallel to the first functional group 34. The second ligand 33B includes a second functional group 41, a negatively charged portion 42, and a positively charged portion 35. The negatively charged portion 42 and the positively charged portion 35 are positioned parallel to the second functional group 41.

FIG. 32 is a conceptual drawing illustrating of yet another quantum dot 31C. Members of the present embodiment that are similar to those described earlier are indicated by similar reference numerals, and detailed description thereof is omitted.

A first ligand 32C and a second ligand 33C are coordinated to the quantum dot 31C. The first ligand 32C includes a first functional group 34, a positively charged portion 35, and a negatively charged portion 42. The positively charged portion 35 and the negatively charged portion 42 are positioned in series with the first functional group 34. The second ligand 33C includes a second functional group 41, a negatively charged portion 42, and a positively charged portion 35. The negatively charged portion 42 and the positively charged portion 35 are positioned in series with the second functional group 41. In both the first ligand 32C and the second ligand 33C, the distance between the negatively charged portion 42 and the quantum dot 31C is larger than the distance between the positively charged portion 35 and the quantum dot 31C.

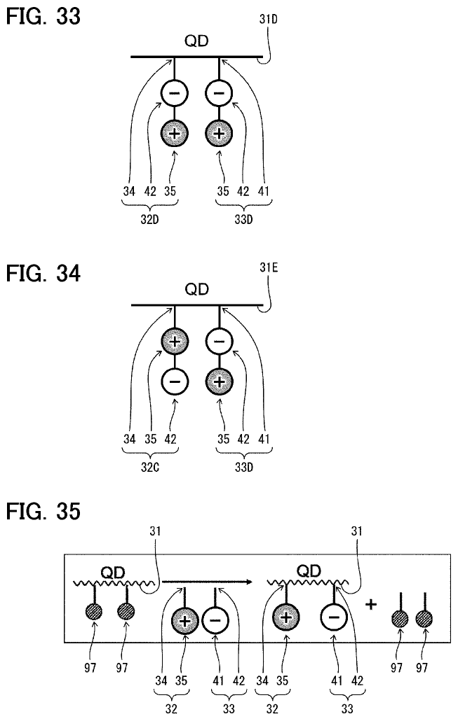

FIG. 33 is a conceptual drawing illustrating of still another quantum dot 31D. Members of the present embodiment that are similar to those described earlier are indicated by similar reference numerals, and detailed description thereof is omitted.

The quantum dot 31D includes a first ligand 32D and a second ligand 33D. The first ligand 32D includes a first functional group 34, a positively charged portion 35, and a negatively charged portion 42. The positively charged portion 35 and the negatively charged portion 42 are positioned in series with the first functional group 34. The second ligand 33D includes a second functional group 41, a negatively charged portion 42, and a positively charged portion 35. The negatively charged portion 42 and the positively charged portion 35 are positioned in series with the second functional group 41. In both the first ligand 32D and the second ligand 33D, the distance between the positively charged portion 35 and the quantum dot 31D is larger than the distance between the negatively charged portion 42 and the quantum dot 31D.

FIG. 34 is a conceptual drawing illustrating of yet still another quantum dot 31E. Members of the present embodiment that are similar to those described earlier are indicated by similar reference numerals, and detailed description thereof is omitted.

The quantum dot 31E includes a first ligand 32C and a second ligand 33D. In the first ligand 32C, the distance between the negatively charged portion 42 and the quantum dot 31E is larger than the distance between the positively charged portion 35 and the quantum dot 31E. In the second ligand 33D, the distance between the positively charged portion 35 and the quantum dot 31E is larger than the distance between the negatively charged portion 42 and the quantum dot 31E.

As described here, the first ligands 32B, 32C, 32D and the second ligands 33B, 33C, 33D in the quantum dots 31B, 31C, 31D, 31E include zwitterionic ions (zwitterions) including a positively charged portion 35 and a negatively charged portion 42.

The quantum dots 31B, 31C, 31D, 31E need only have at least a pair of ionic functional groups selected from cationic functional groups and anionic functional groups and preferably include the same quantity of cationic functional groups and anionic functional groups.

FIG. 35 is a diagram illustrating a method of modifying the quantum dot 31 by modification group replacement. Members of the present embodiment that are similar to those described earlier are indicated by similar reference numerals, and detailed description thereof is omitted.

The quantum dot 31 may be modified with a first ligand 32 and a second ligand 33 by modification group replacement in which the ligands 97 coordinated to the quantum dot 31 are replaced by the first ligand 32 and the second ligand 33.

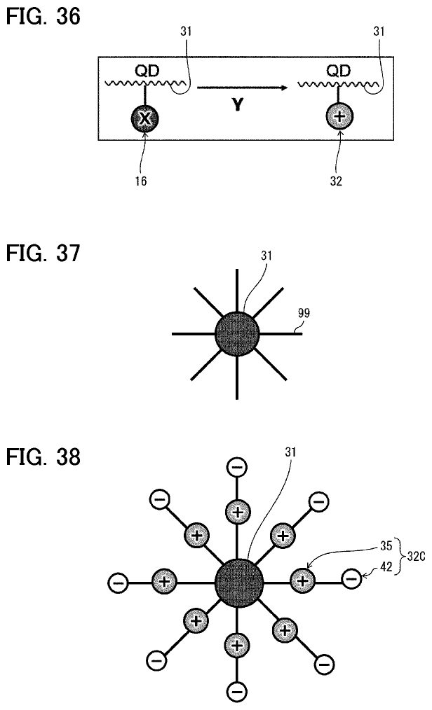

FIG. 36 is a diagram illustrating a method of modifying the quantum dot 31 by graft modification. Members of the present embodiment that are similar to those described earlier are indicated by similar reference numerals, and detailed description thereof is omitted.

The quantum dot 31 may be modified by converting a reactive functional group 16 coordinated to the quantum dot 31 to a first ligand 32 by graft modification afterwards. Examples of the functional group 16 that can be converted by graft modification include an amino group, a halogeno group, a hydroxy group, and a vinyl group.

These methods of modification group replacement and graft modification may be combined for use.

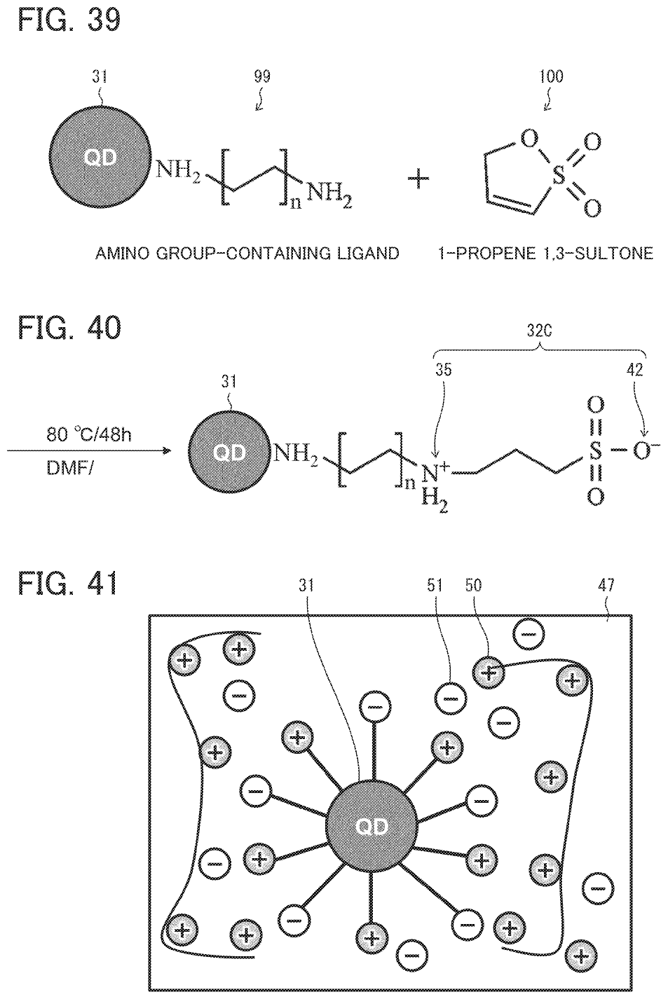

FIGS. 37 to 40 are diagrams illustrating other methods of modifying the quantum dot 31 by graft modification. Members of the present embodiment that are similar to those described earlier are indicated by similar reference numerals, and detailed description thereof is omitted.

First, diamine 100 is further added and mixed with the quantum dot 31 to which ligands 99 with an amino acid are coordinated. These quantum dots 31 contain CdSe. For instance, hexamethylenediamine is coordinated to the quantum dots 31 for preparation. Then, these quantum dots 31 and the materials listed below are mixed at 80° C. for 48 hours to obtain sulfonic acid-amide salt.
1-propene 1,3-sultone (8.0 mL, 0.1 mmol)
dimethylformamide (DMF, 120 mL)

Hence, the quantum dots 31 are obtained which are modified by the first ligands 32C including the positively charged portions 35 and the negatively charged portions 42.

FIG. 41 is a diagram illustrating an exemplary ionic liquid 47. Members of the present embodiment that are similar to those described earlier are indicated by similar reference numerals, and detailed description thereof is omitted.

The ionic liquid 47 may include cations 50 and anions 51 either of which form a polymer. FIG. 41 shows an example where the cations 50 form a polymer.

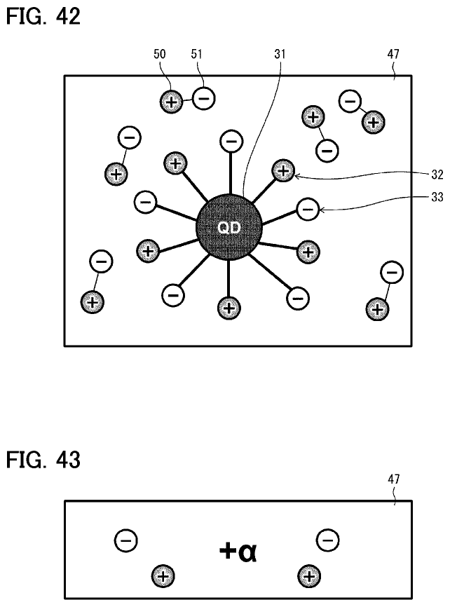

FIG. 42 is a diagram illustrating another exemplary ionic liquid 47. Members of the present embodiment that are similar to those described earlier are indicated by similar reference numerals, and detailed description thereof is omitted.

The ionic liquid 47 may be a liquid of zwitterionic ions (zwitterion) in which cations 50 and anions 51 form molecular pairs.

FIG. 43 is a diagram illustrating yet another exemplary ionic liquid 47. Members of the present embodiment that are similar to those described earlier are indicated by similar reference numerals, and detailed description thereof is omitted.

The ionic liquid 47 may include another ionic liquid or solvent species or another carrier transport material.

The present invention is not limited to the description of the embodiments above and may be altered within the scope of the claims. Embodiments based on a proper combination of technical means disclosed in different embodiments are encompassed in the technical scope of the present invention. Furthermore, new technological features can be created by combining different technical means disclosed in the embodiments.

### REFERENCE SIGNS LIST

1 Anode
2 Hole Transportation Layer
4 Electron Transportation Layer
3 Light-Emitting Layer
5 Cathode
7 Spacer (Frame-shaped Resin Member)
10A Light-emitting Element
31 Quantum Dot
31R Quantum Dot (Third Quantum Dot)
31G Quantum Dot (Second Quantum Dot)
3 1B Quantum Dot (First Quantum Dot)
32 First Ligand
33 Second Ligand
34 First Functional Group
Positively Charged Portion
36 First Main Chain
41 Second Functional Group
42 Negatively Charged Portion
43 Second Main Chain
47 Ionic Liquid (Normal-Temperature Molten Salt)
71 Liquid-injection Hole

1. A light-emitting element comprising:
an anode;
a cathode; and
a light-emitting layer between the anode and the cathode, wherein
the light-emitting layer comprises:
a quantum dot;
a plurality of first ligands each including a first functional group coordinated to the quantum dot and further including a positively charged portion;
a plurality of second ligands each including a second functional group coordinated to the quantum dot to which the plurality of first ligands are coordinated and further including a negatively charged portion; and
a normal-temperature molten salt in which the quantum dot is dispersed.

2. The light-emitting elements according to claim 1, wherein each of the plurality of first ligands includes a first main chain of a saturated or unsaturated C₃-C₂₀ hydrocarbon between the first functional group and the positively charged portion.

3. The light-emitting elements according to claim 2, wherein the positively charged portion is contained in a functional group bonded to a carbon that is located farthest along the first main chain from a carbon to which the first functional group is bonded.

4. The light-emitting elements according to claim 1, wherein each of the plurality of second ligands includes a second main chain of a saturated or unsaturated C₃-C₂₀ hydrocarbon between the second functional group and the negatively charged portion.

5. The light-emitting elements according to claim 4, wherein the negatively charged portion is contained in a functional group bonded to a carbon that is located farthest along the second main chain from a carbon to which the first functional group is bonded.

6. The light-emitting elements according to claim 1, wherein
each of the plurality of first ligands includes the first functional group and a portion that is only positively charged, and
each of the plurality of second ligands includes the second functional group and a portion that is only negatively charged.

7. The light-emitting elements according to claim 1, wherein
each of the plurality of first ligands further includes a negatively charged portion, and
each of the plurality of second ligands further includes a positively charged portion.

8. The light-emitting elements according to claim 7, wherein
in each of the plurality of first ligands, a distance between the quantum dot and the negatively charged portion is larger than a distance between the quantum dot and the positively charged portion, and
in each of the plurality of second ligands, a distance between the quantum dot and the positively charged portion is larger than a distance between the quantum dot and the negatively charged portion.

9. The light-emitting elements according to claim 1, wherein in the quantum dot including the plurality of first ligands and the plurality of second ligands, the positively charged portions are 0.8 times to 1.2 times, both inclusive, as many as the negatively charged portions.

10. The light-emitting elements according to claim 1, wherein
a frame-shaped resin member is formed on either the anode or the cathode; and
the light-emitting layer is formed inside the frame-shaped resin member.

11. The light-emitting elements according to claim 1, wherein
a hole transportation layer is provided between the anode and the light-emitting layer,
an electron transportation layer is provided between the cathode and the light-emitting layer,
a frame-shaped resin member is formed on either the hole transportation layer or the electron transportation layer, and
the light-emitting layer is formed inside the frame-shaped resin member.

12. The light-emitting elements according to claim 1, wherein
the quantum dot comprises a plurality of quantum dots,
the light-emitting layer further comprises a porous resin,
the normal-temperature molten salt in which the plurality of quantum dots are dispersed is liquid, and
the normal-temperature molten salt is retained by the porous resin.

13. (canceled)

14. (canceled)

15. The light-emitting elements according to claim 1, wherein
the quantum dot comprises a plurality of quantum dots, and
the plurality of quantum dots account for 0.5 wt % to 10 wt %, both inclusive, of the normal-temperature molten salt.

16. (canceled)

17. (canceled)

18. A method of manufacturing a light-emitting element, the method comprising:
a step of forming an anode;
a step of forming a cathode; and
a step of forming a light-emitting layer, wherein
the step of forming a light-emitting layer comprises:
a first step of forming a resin member in a frame shape on either the anode or the cathode; and
a second step of forming:
a quantum dot;
a plurality of first ligands each including a first functional group coordinated to the quantum dot and further including a positively charged portion;
a plurality of second ligands each including a second functional group coordinated to the quantum dot to which the plurality of first ligands are coordinated and further including a negatively charged portion; and
a liquid normal-temperature molten salt in which the quantum dot is dispersed inside the frame-shaped resin member.

19. The method according to claim 18, wherein in the first step, the resin member is formed on the anode or the cathode.

20. The method according to claim 18, wherein
the step of forming an anode further comprises a step of forming a hole transportation layer on the anode,
the step of forming a cathode further comprises a step of forming an electron transportation layer on the cathode, and
in the first step, the resin member is formed on the hole transportation layer or the electron transportation layer.

21. The method according to claim 18, wherein
the quantum dot comprises a plurality of quantum dots, and
in the second step, the normal-temperature molten salt in which the plurality of quantum dots are dispersed is retained by a porous resin formed inside the frame-shaped resin member.

22. A method of manufacturing a light-emitting element, the method comprising:
a step of forming an anode;
a step of forming a cathode;
a step of attaching the anode and the cathode together; and
a step of forming a light-emitting layer, wherein
the step of attaching the anode and the cathode together comprises:
a first step of forming a resin member in a frame shape, except for a portion for a liquid-injection hole, on either the anode or the cathode; and
a second step of attaching the anode and the cathode together and via the resin member, the step of forming a light-emitting layer comprises:
a step of injecting, between the anode and the cathode that are attached together via the liquid-injection hole, a liquid comprising:
a quantum dot;
a plurality of first ligands each including a first functional group coordinated to the quantum dot and further including a positively charged portion;
a plurality of second ligands each including a second functional group coordinated to the quantum dot to which the plurality of first ligands are coordinated and further including a negatively charged portion; and
a normal-temperature molten salt in which the quantum dot is dispersed; and
subsequently to the step of injecting a liquid, a step of sealing the liquid-injection hole.

23. The method according to claim 22, wherein in the first step, the resin member is formed on the anode or the cathode.

24. The method according to claim 22, wherein
the step of forming an anode further comprises a step of forming a hole transportation layer on the anode,
the step of forming a cathode further comprises a step of forming an electron transportation layer on the cathode, and
in the first step, the resin member is formed on the hole transportation layer or the electron transportation layer.
